(19) United States
(12) Patent Application Publication
(10) Pub. No.: US 2025/0335650 A1
(43) Pub. Date: Oct. 30, 2025

(54) PRODUCTION LINE DESIGN SYSTEM

(71) Applicant: Hitachi, Ltd., Tokyo (JP)

(72) Inventors: Daisuke TSUTSUMI, Tokyo (JP); Kaoru KITAJIMA, Tokyo (JP)

(21) Appl. No.: 19/077,444

(22) Filed: Mar. 12, 2025

(30) Foreign Application Priority Data
Apr. 30, 2024 (JP) 2024-073641

(51) Int. Cl. G06F 30/17

(52) U.S. Cl. CPC G06F 30/17

(57) ABSTRACT

A production line design system stores: facility information that indicates facilities used in a production line of an object product and arrangement levels of regions in which the facilities are respectively arranged, in which the regions have an inclusion relationship, and arrangement restriction information that defines the arrangement restriction of the facilities by dividing arrangement restriction of the facilities into restriction levels that correspond to the regions that have the inclusion relationship. The production line design system extracts a facility arrangement possible area in the respective arrangement levels based on the facility information and the arrangement restriction information, and the decides an arrangement pattern candidate of the facilities with respect to the extracted respective arrangement possible areas based on the facility information and the arrangement restriction information.

### CLAIM OF PRIORITY

The present application claims priority from Japanese patent application JP 2024-073641 filed on Apr. 30, 2024, the content of which is hereby incorporated by reference into this application.

### TECHNICAL FIELD

The present invention relates to a production line design.

### BACKGROUND ART

In Patent Literature 1, there is the description “In a floor layout preparation method, an operation area for performing a preparation operation before starting operations of production facilities is arranged within a floor on which the production facilities are arranged based on operation frequency information including operation frequency at which operations are performed in the production facility; and arrangement information that includes a facility layout of the plurality of production facilities (ST5), and a floor layout for arranging the production facilities and the operation area on the floor is prepared based on set operation area (ST6)”.

### CITATION LIST

### Patent Literature

Patent Literature 1: Japanese Unexamined Patent Application Publication No. 2020-123056

### SUMMARY OF INVENTION

### Technical Problem

With the use of the technique described in the above-mentioned Patent Literature 1, the operation area can be provided at the appropriate position on the floor on which the production facilities are arranged. However, such a technique can be realized on the premise that the information on the configurations and the arrangements of the production facilities are already given or known and hence, the technique cannot decide the configurations of the production facilities that can be arranged on the floor. That is, to acquire the solution that simultaneously satisfies both the appropriate configurations of the production facilities and the appropriate arrangement of the production facilities with respect to the floor on which the production facilities can be arranged, it is necessary to perform an optimization calculation for finding such solution from enormous combinations and hence, the technique is not applicable to practical use.

It is an object of the present invention to provide both information on a step design that includes the configurations of facilities of a production line and information on an arrangement design that includes the arrangement of the facilities.

### Solution to Problem

The present application includes a plurality of solutions that solve at least a portion of the above-mentioned problems. The following examples described hereinafter are named as such solutions.

A production line design system according to one aspect of the present invention stores: facility information that indicates facilities used in a production line of an object product and arrangement levels of regions having an inclusion relationship in which the facilities are respectively arranged; and arrangement restriction information that defines the arrangement restriction of the facilities by dividing arrangement restriction of the facilities into restriction levels that correspond to the regions that have an inclusion relationship. The production line design system extracts a facility arrangement possible area in the respective arrangement levels based on the facility information and the arrangement restriction information, and the decides an arrangement pattern candidate of the facilities with respect to the extracted respective arrangement possible areas that are extracted based on the facility information and the arrangement restriction information.

### Advantageous Effects of Invention

According to one aspect of the present invention, it is possible to provide a technique that can make a production line design plan that suppresses an investment cost with ease.

Objects, configurations, and effects other than the above will be apparent from the description of the following embodiments.

### BRIEF DESCRIPTION OF DRAWINGS

FIG. 1 is a view illustrating a configurational example of a production line design device.

FIG. 2 is a view illustrating an example of product information.

FIG. 3 is a view illustrating an example of facility information.

FIG. 4 is a view illustrating an example of operation time information of part-resource candidates.

FIG. 5 is a view illustrating an example of arrangement restriction information.

FIG. 6 is a view illustrating an example of step design information.

FIG. 7A is a view illustrating an example of arrangement design information.

FIG. 7B is a view illustrating an example of arrangement design information.

FIG. 8A is a view illustrating a calculation example of an arrangement pattern at a floor level.

FIG. 8B is a view illustrating a calculation example of an arrangement pattern at a floor level.

FIG. 9A is a view illustrating a calculation example of an arrangement pattern at a floor level.

FIG. 9B is a view illustrating a calculation example of an arrangement pattern at a floor level.

FIG. 9C is a view illustrating a calculation example of an arrangement pattern at a floor level.

FIG. 9D is a view illustrating a calculation example of an arrangement pattern at a floor level.

FIG. 10 is a view illustrating a hardware configurational example of a production line design device.

FIG. 11 is a view illustrating the flow of production line design processing.

FIG. 12 is a view illustrating an example of a display screen of an arrangement pattern result.

FIG. 13 is a view illustrating an example of a display screen of arrangement design information.

### DESCRIPTION OF EMBODIMENTS

In an embodiment described hereinafter, for the sake of convenience, when necessary, the description is made by dividing a production line design device into a plurality of sections or embodiments. However, unless otherwise explicitly described, these sections and the embodiments are not irrelevant to each other, and these sections and embodiments have the relationship where one is a modification, a detail, a complementary description or the like of a part or the entirety of the other.

Further, in the embodiments described hereinafter, in a case where the number of elements and the like (including the number, numerical values, quantities, ranges and the like) are referred to, except for a case where the number is particularly explicitly specified, and a case where the number is apparently limited to specific numbers and the like, the number is not limited to the specific numbers and may be equal to the specific number or more or less than the specific number.

Further, in the embodiments described hereinafter, it is needless to say that, with respect to the constitutional elements (also including element steps and the like), except for a case where the constitutional elements are particularly explicitly specified, and a case where these constitutional elements are apparently indispensable in principle and the like, it is not always the case that these constitutional elements are indispensable.

In the same manner, in the embodiments described hereinafter, when the shapes, positional relationships and the like of the constitutional elements and the like are referred to, except for the case where these are not particularly explicitly specified, and the case where these are not apparently specified in principle and the like, these also include the shapes, the positional relationships and the like that are similar to or substantially equal to these shapes, positional relationships and the like. The same substantially goes for the above-mentioned numerical values ranges.

Further, in all drawings for describing the embodiments, the same reference sign is given to identical members in principle, and the repeated description of the identical members is omitted. However, even with respect to the identical members, in a case where there is a high possibility that the confusion occurs when the naming of the members is shared in common before and after an environment is changed, different reference signs or different names may be given.

Hereinafter, the respective embodiments of the present invention are described with reference to drawings.

In general, in the design of a production line that is constituted of robots, based on an object product and a production condition that a client offers, a step design that decides operation units (steps) and facilities in charge of the operation units is performed, and detailed designs that correspond to the step design such as an arrangement design, a facility design, a control design and the like are performed.

Further, in general, the step design, the arrangement design, the control design and the facility design described above are sequentially studied or reviewed in a waterfall type as independent issues respectively.

In the design of the production line, it is often the case that a new line is constructed by updating a partial area of an existing plant. In conventional waterfall-type development steps in which the arrangement design is performed using the facility configuration decided in the step design and a conveyance system that connects the facilities as an input, in a case where the arrangement restriction is not sufficiently satisfied, a return work that requires the restudy starting from the step design occurs. Accordingly, in view of the above, there has been a demand for a technique that enables the generation and the evaluation of an optimum step design plan that takes into account the arrangement restriction.

In this embodiment, the description is made with respect to a production line design system that satisfies a demand of a client. That is, such a production line design system satisfies the restriction on a floor of a plant that constitutes a production line and target tact times of the production line, and realizes the generation of step design information and the arrangement design information of the production line that optimizes the target function.

In the embodiment, described hereinafter, “input unit”, “output unit”, and “communication unit” may be each formed of such one or more interface devices. Such one or more interface devices may be at least one of the following interface devices.

One or more Input/Output (I/O) interface devices. The I/O interface device is an interface device for at least one of an I/O device and a remote display computer. The I/O interface device for the display computer may be a communication interface device. At least one I/O device may be a user interface device, for example, either one of an input device such as a keyboard or a pointing device and an output device such as a display device.

One or more communication interface devices. One or more communication interface devices may be one or more communication interface devices of the same type (for example, one or more network interface cards (NIC)), or communication interface devices of two or more different kinds (for example, NIC and host bus adapter (HBA)).

In the description made hereinafter, “memory” is an example of one or more memory devices that constitute one example of one or more storage devices. The memory may typically be a main storage device. At least one memory device in the memory may be a volatile memory device or a non-volatile memory device.

In the description made hereinafter, an “external storage device” may be one or more permanent storage devices that constitute one example of one or more storage devices. The permanent storage device may typically be a non-volatile storage device (for example, an auxiliary storage device). To be more specific, for example, the permanent storage device may be a hard disk drive (HDD), a solid state drive (SSD), a non-volatile memory express (NVME) drive, or a storage class memory (SCM).

In the description made hereinafter, “storage unit” or “external storage device” may be, out of a memory and a permanent storage device, the memory or both of the memory and the permanent storage device.

In the description made hereinafter, “processing unit” or “processer” may be constituted of one or more processer devices. At least one processer device may typically be a microprocessor device such as a central processing unit (CPU). However, the processer device may be a processor device of a different kind such as a graphics processing unit (GPU). At least one processor device may be a single core or a multi-core. At least one processor device may be a processor core. At least one processor device may be a processor device in a broad definition such as a circuit that is a collective body of gate arrays expressed using a hardware description language that performs a part or the entirety of processing (for example, a field-programmable gate array (FPGA), a complex programmable logic device (CPLD) or an application specific integrated circuit (ASIC)).

In the description made hereinafter, a function may be described by using an expression “yyy unit”. However, a function may be realized by allowing a processor to execute one or more computer programs, may be realized by one or more hardware circuits (for example, FPGA or ASIC), or may be realized by the combinations of these processing. In a case where a function is realized by allowing a processor to execute a program, predetermined processing may be performed by suitably using a storage device and/or an interface device or the like and hence, the function may be considered to form at least a part of the processor. Processing described using a function as a subject, may be processing that a processor or a device that includes the processor performs. A program may be installed from a program source. The program source may be, for example, a record medium (for example, a non-volatile record medium) that is readable by a program distributed computer or a computer. The description of respective function is made for an exemplifying purpose as an example, and a plurality of functions may be assembled as one function, or one function may be divided into a plurality of functions.

In the description made hereinafter, there are cases where processing is described using “program” or “processing unit” as a subject. However, the processing described using a program as a subject may be processing that a processor or a device that includes the processor performs. Further, two or more programs may be realized as one program, or one program may be realized by two or more programs.

In the description made hereinafter, information by which an output is obtained in response to an input is described using an expression “x×x table”. However, the information may be a table having any structure, or a learning model represented by a neural network, a genetic algorithm or a random forest that generates an output in response to an input. Accordingly, “x×x table” may be expressed as “xxx information”. In the description made hereinafter, the configurations of the respective tables are exemplified as an example. One table may be divided into two or more tables, or the entirety or a part of two or more tables may form one table.

Further, in the description made hereinafter, a production line design system may be a system constituted of one or more physical computers, or a system that is realized on a physical calculation resource group (for example, cloud infrastructure) (for example, cloud computing system). “Displaying” of the display-use information that the production line design system performs, may be displaying display-use information on a display device that the computer includes, or may be transmitting of display-use information to a display-use computer by the computer (in the latter case, display-use information is displayed by the display-use computer).

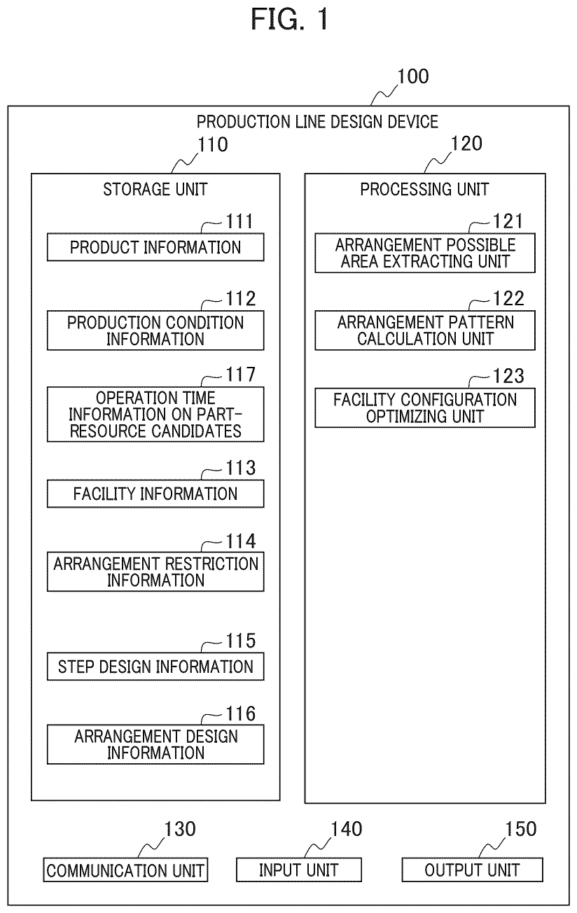

FIG. 1 is a view illustrating a configurational example of a production line design system. In the configurational example illustrated in FIG. 1, a production line design system is constituted of a production line design device 100. The constitutional elements of the production line design system is disposed in a manufacturing site (area) or outside the manufacturing site. The production line design system may include a device group that corresponds to a use environment where a display-use computer and the like are communicably connected to the production line design system via a network not illustrated in the drawing.

Although not illustrated in the drawing, the network is formed of, any one of, for example, a communication network that uses a part or the entirety of a general public network such as a local area network (LAN), a wide area network (WAN), a virtual private network (VPN), the internet and the like or, a mobile phone communication network, the combinations of these networks. The network may be a radio communication network using Wi-Fi (registered trademark), 5G (Generation) or the like.

The production line design device 100 decides the configurations and the arrangement of the production facilities by allocating operation steps relating to assembling of an assembled product to the respective production facilities.

The production line design device 100 includes logical constitutional elements constituted of a storage unit 110, a processing unit 120, a communication unit 130, an input unit 140, and an output unit 150.

### <Storage Unit>

The storage unit 110 stores product information 111, production condition information 112, facility information 113, arrangement restriction information 114, step design information 115, arrangement design information 116, operation time information 117 for part-resource candidates.

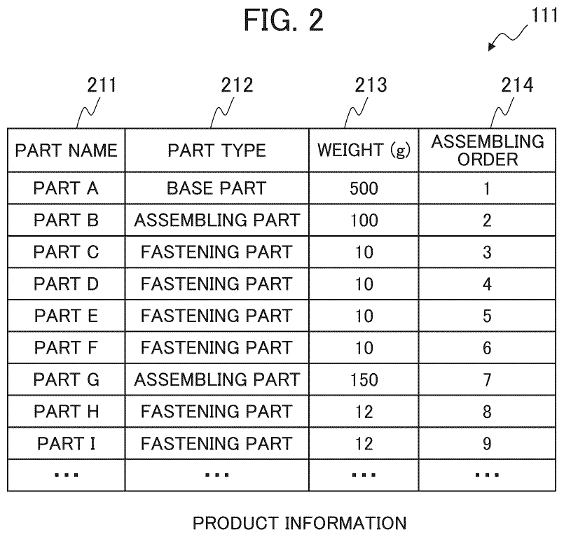

FIG. 2 is a view illustrating an example of the product information 111. The product information 111 holds the part configurations, the part specifications, and the production specification of products manufactured on the production line in the form of a table. As the part configurations, part names 211 of the respective parts are stored. As the part specifications, the classification based on the shapes of the respective parts, that is, part types 212 and weights 213 of the parts are stored. As the production specification, by taking the assembled product as an example, an assembling order 214 of the parts is stored. The production specification may include information on types of operations such as working and welding and the order of such operations besides the assembling. Further, the production specification may be held independently as information different from product information.

The production condition information 112 indicates a required specifications for designing the production line. As the required specifications, for example, a target tact time of an object product is stored. Corresponding to the target tact time, required values for the numbers of the production facilities that constitute a production line and abilities of the production facilities are changed. A target tact time may be obtained in such a manner that an object production amount and a working time of the production line are stored in place of the target tact time, and the target tact time is calculated by dividing the target production amount by the working time.

Further, as a required specification, for example, a target function of the production line is stored. As the target function, for example, a minimization of an investment cost, a minimization of tact time, a minimization of irregularities in a tact time between steps and the like can be defined.

Further, as a required specification, for example, a size of a floor of a plant where a production line is arranged is memorized. The sizes and the number of the facilities that can be arranged on the floor can be changed corresponding to the size of the floor. An arrangement restriction that defines areas such as existing facilities, safety passages and the like in the floor that cannot be arranged are included in the arrangement restriction information 114.

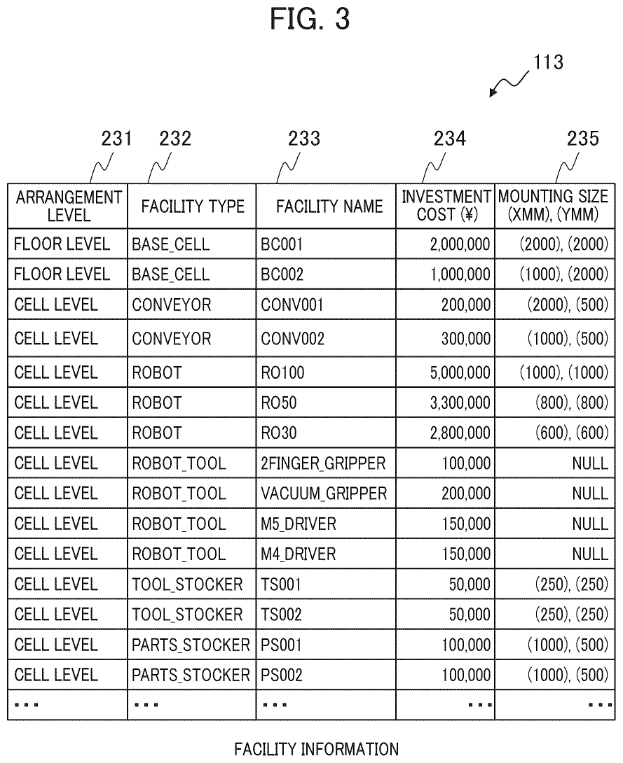

FIG. 3 is a view illustrating an example of the facility information 113. The facility information 113 holds the facility specification of a group of facility candidates that constitute a production line and hierarchical information that enables the arrangement of the facilities in the form of a table. As the facility specification, the classification based on usages of the facilities, that is, a facility type 232, a facility name 233, an investment cost 234 that is a cost at the time of purchasing the facilities, and facility sizes 235 that indicate regions necessary for arranging the facilities are stored. In this example, the facility size 235 prescribes only longitudinal and lateral sizes (length and width) as viewed from an upper side. Together with these values, a height of the facility may be stipulated.

As the facility information, the relationship between the facilities may be stored. For example, ROBOTs, a TOOL STOCKER and the like of a facility type are arranged on the BASE_CELLS. A ROBOT_TOOL of a facility type is connected to a distal end of the ROBOT. In a case where the ROBOT is used by exchanging a plurality of ROBOT_TOOLS, the TOOL STOCKER is necessary as a facility for holding the tools that are not used, and the ROBOT_TOOLS are held by the TOOL STOCKER.

As the hierarchical information that enables the arrangement of the facilities, an arrangement level 231 is stored. The respective facilities are arranged in regions that the arrangement levels indicate. The arrangement level constitutes the hierarchical structure of the regions in which the facilities are arranged. In the hierarchical structure, the arrangement level is changed in a stepwise manner from the arrangement level having a larger region (higher-order layer) to the arrangement level having a narrower region (lower-order layer). The narrower region is included in the larger region (an inclusion relationship existing between the regions). The larger region can include one or more smaller regions. In this specification, two arrangement levels are described as an example. These levels are a floor level and a cell level. Each facility is arranged in either the floor or the cell.

The other arrangement levels may be added or a portion of these levels may be omitted. For example, a line level may be defined between the floor level and a cell level, and a frame that is arranged at the line level may be prepared. The shape and the size of the frame may define the profile of the space of the line. Alternatively, as a lower-order level of the cell level, the level of the facilities disposed in the cell such as the robot level or the like may be defined, and some parts may be prepared as facilities arranged in the robot. The regions at the arrangement levels are set smaller from the highest-order level to the lowest-order level in a stepwise manner. That is, the regions at the cell level are included in the region at the floor level.

The facility information 113 illustrated in FIG. 3 indicates, as the arrangement level, the floor level of the plant in which the production line is constituted, for example. As the facility type capable of being arranged at the floor level, BASE_CELL_is named. BASE_CELL can include one or a plurality of platforms prepared as standard facilities of the cell, for example.

The cell is an example of a unit that constitutes the production line. To take assembling as an example, in a series of assembling operations, a unit that is formed by collecting a plurality of assembling operations forms a step. For example, in the product information 111 illustrated in FIG. 2, the assembling order 214 indicates an order of the assembling operations, and each entry corresponds to one operation. One or more continuous entries constitute one step. It is important that a time of each step does not exceed a target tact time, and a time is levelled between the steps as much as possible. A state where the leveling is not achieved means that a wait is generated in a certain step and hence, time is wasted. A unit of the facility that corresponds to the step constitutes the cell. The facility size 235 of BASE_CELL agrees with the size of the cell.

The arrangement level of a group of facility candidates that can be arranged in the cell is the cell level. One cell includes, for example, a standard facility, a robot or a dedicated facility (an inspection device or the like) that constitutes a main facility, and a plurality of facilities (tools, a stocker and the like) that are necessary in association with the main facilities. The standard facility of the cell may also include a main facility and facilities associated with the main facility.

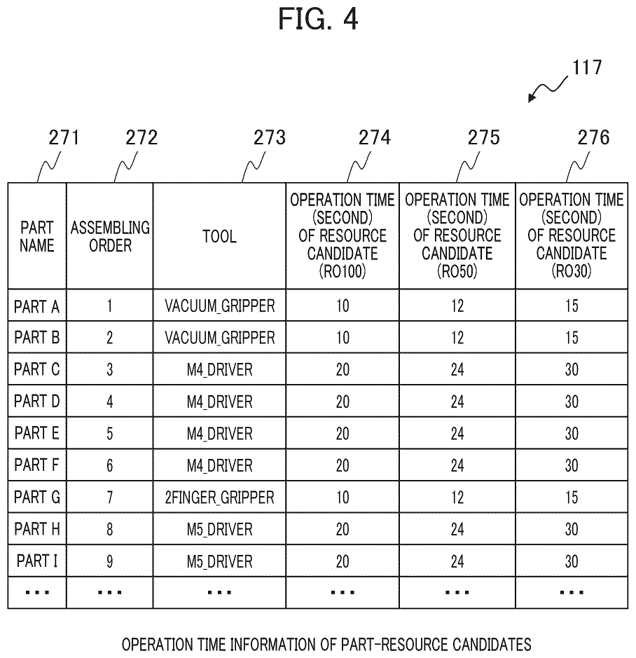

FIG. 4 is a view illustrating an example of operation time information 117 of parts-resource candidates. With respect to the operation time information 117 of the parts-resource candidates as the information shared in common with the product information 111, at least part names 271 and an assembling order 272 are stored. Further, tools 273 necessary for performing operations (assembling in this embodiment) of respective parts are stored.

The tool 273 is, in the example of the assembling of a robot, is selected from facility names 233 of an entry where the facility type 232 of the facility information 113 is classified to “ROBOT_TOOL”. Further, operation times of respective resource (robot in this embodiment) candidates capable of performing the operations of the respective parts are stored. In the example illustrated in FIG. 4, as the resource candidates, three kinds of facilities having the facility names 233 of “RO100”, “RO 50”, and “RO 30” where the facility type 232 of the facility information 113 is classified into “ROBOT” are listed. Information on operation times 274, 275, 276 of “RO100”, “RO 50”, and “RO 30” are stored.

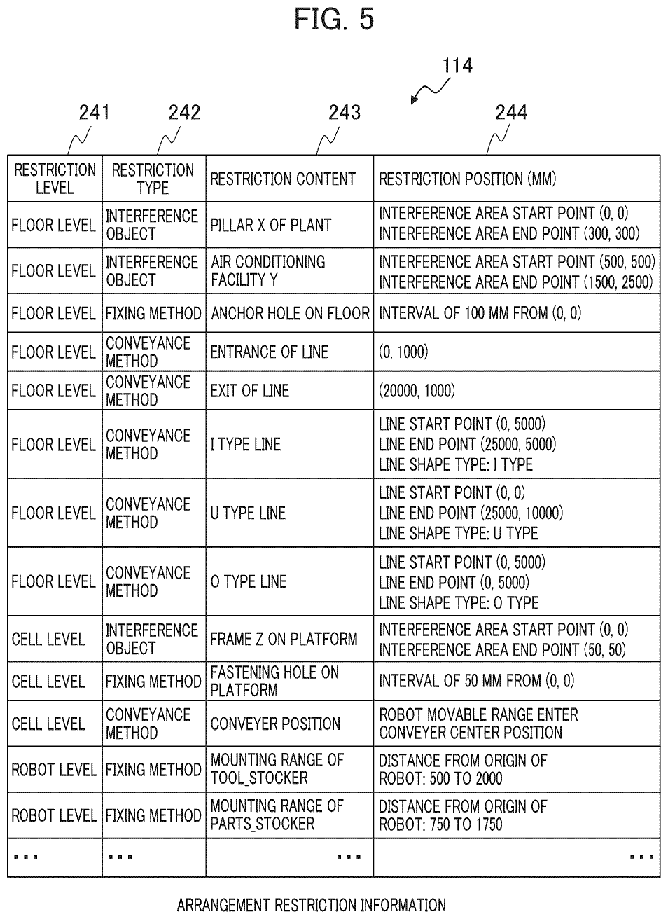

FIG. 5 is a view illustrating an example of the arrangement restriction information 114. The arrangement restriction information 114 holds information on restrictions relating to the floor of the plant on which the production line is designed, and the arrangement of the facility candidate group that constitutes the production line in the form of a table. A restriction level 241 that is information indicating a layer of the arrangement restriction, a restriction type 242 that is information indicating kinds of the arrangement restrictions, a restriction content 243 that is information indicating the detail of the arrangement restriction, and the restriction positions 244 are stored. In the example illustrated in FIG. 5, the restriction level 241 includes a line level and a robot level in addition to two layers consisting of the floor level and the cell level included in the arrangement level.

The line level is defined as a layer between a floor level and a cell level. By defining a line level, the restriction on a line shape can be defined such as a straight-line I type line, a circumferential O type line and the like can be defined.

The robot level is defined as a layer below the cell level. By defining the robot level, the standard arrangement of facilities associated with the robot can be defined. Further, the restriction level of facilities disposed in a cell different from the robot may be also defined.

As the restriction level, for example, other levels such as a dedicated facility level, a conveyance level or the like may be defined. Some levels such as a line level and/or a robot level, for example, may be omitted.

The restriction level 241 corresponds to a region level that imparts the restriction on the arrangement of the facilities. In the same manner as the arrangement level 231, the restriction level 241 is changed from the restriction level having a larger region (higher-order layer) to the restriction level having a smaller region (lower-order layer) in a stepwise manner. The smaller region is included in the larger region. The wider region may include one or more narrower regions. The restriction level indicates the region that becomes the reference of the restriction in the arrangement of the facilities.

The restriction level 241 includes some or all layers that the arrangement level 231 of the facility information 113 indicates. In this specification, three restriction levels are described as an example. These restriction levels are a floor level, a cell level, and a robot level. Other restriction levels may be added to these levels or some of these levels may be omitted. The region of the restriction level is made smaller from a highest-order level to a lowest-order level in a stepwise manner. That is, the region of the cell level is included in the region of the floor level, and the region of the robot level is included in the region of the cell level.

As the restriction type 242, for example, an interference object, a fixing method, a conveyance method and the like are named. As an interference object on the floor level (in the floor), a pillar, an air conditioning facility and the like in a plant is named. Further, an area where the facility cannot move such as a safety passage can be also regarded as the interference object. Further, as the interference object on the cell level (in the cell), a frame disposed on a platform of the cell or the like is named.

As the arrangement restriction on the fixing method at the floor level, the restriction that the facilities are arranged in conformity with anchor holes formed in the floor at an equal interval is named. As the arrangement restriction on the fixing method at the cell level, the restriction on fixing the facility in conformity with fastening holes or rails disposed on an upper surface of a platform is named. As the fixing method at the robot level, an arrangement range of TOOL STOCKER and an arrangement range of PARTS STOCKER are designated.

As the arrangement restriction on the conveyance method at the floor level, an entrance and an exit of a line in an object area are defined as an input in conformity with a conveyance route in a plant. As the arrangement restriction of the conveyance method at the floor level, a line shape, that is, a shape type, a start point and an end point are designated. As examples of the line shape, an I type, a U type, and an O type are named. As the arrangement restriction on the conveyance method at the cell level, in a case where a product flows in a line by a conveyer or the like, there is a restriction that a movable range of robot or the like is located at a position where the product reaches the conveyer.

The restriction content 243 stores specific contents of the restriction. With respect to the restriction position 244, information relating to specific numerical values of the restriction is stored. For example, in a case where a pillar X exists in a plant as an interference object at the floor level, and the pillar X has an interference range from a start point coordinates (0, 0) to an end point coordinates (300, 300) in an object area. That is, there is the pillar having a square cross section of 300 mm. In this case, it is understood that the facility cannot be arranged. As described above, the restriction level that is equal to the arrangement level and the restriction level lower than the arrangement level has a possibility of becoming the restriction with respect to an arrangement of the facility. For example, the arrangement level of the TOOL_STOCKER and the PARTS_STOCKER are at the cell level and hence, these facilities receive the restriction at the cell level and the robot level. There is a possibility that facilities that are irrelevant to the restriction at the lower-order level exist. For example, the arrangement level of ROBOT is the cell level, and hence, in the arrangement of ROBOT in the cell, ROBOT does not receive the restriction at the robot level, and receives only the restriction at the cell level.

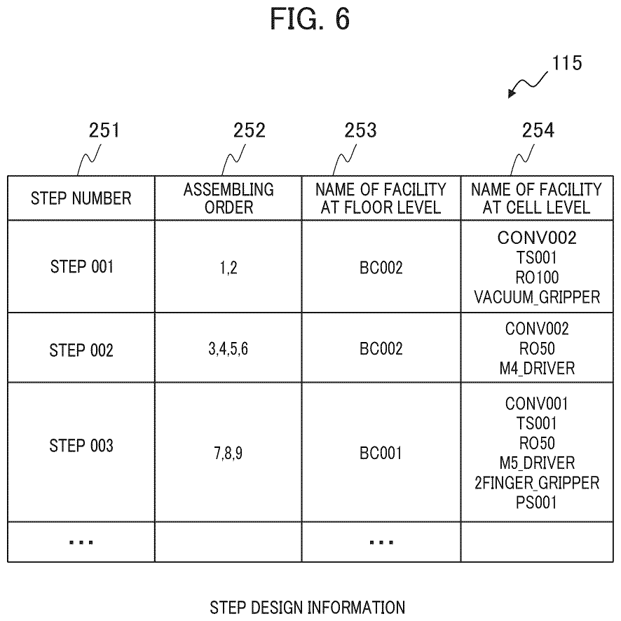

FIG. 6 is a view illustrating an example of the step design information 115. The step design information 115 is one mode of output information of the production line design device 100. As the step design information 115, a step number 251 that constitutes the production line, an assembling order 252 indicating operations that the step is in charge of, a facility name 253 at the floor level that constitutes the step, and a facility name 254 at the cell level are stored.

In the step design information 115, the assembling order 252 corresponds to the assembling order 214 of the product information 111 illustrated in FIG. 2. That is, the assembling order is an example of the operation that forms a part of the production line, and may be information on the operation order such as welding and working. Further, the facility name 253 at the floor level and the facility name 254 at the cell level correspond to the facility name 233 of the facility information 113 illustrated in FIG. 3. The number of items of the step design information 115 may be changed corresponding to the number of layers of the arrangement level.

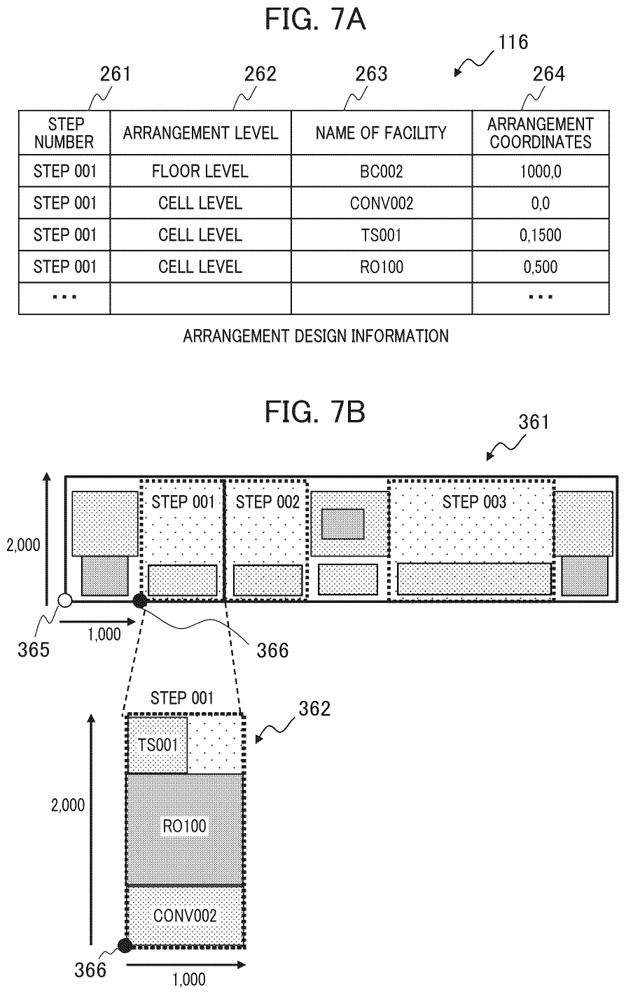

FIG. 7A is a view illustrating an example of the arrangement design information. The arrangement design information 116 is one mode of output information of the production line design device. As the arrangement design information 116, a step number 261 corresponding to the step number 251 stored in the step design information 115, an arrangement level 262 of constitutional facilities, a facility name 263, and an arrangement coordinates 264 that is start point coordinates where the facility is arranged, are stored.

A step 001 of the step design information 115 is constituted of five facilities. Among these facilities VACCUM_GRIPPER is directly connected to robot RO100 and hence, the arrangement of VACCUM_GRIPPER in the cell is unnecessary. Accordingly, in the arrangement design information 116, as the facilities in the step 001, information on four facilities excluding VACCUM_GRIPPER is stored.

FIG. 7B illustrates an example of an arrangement layout 361 at the floor level and an arrangement layout 362 at the cell level. With respect to the arrangement layout 361 at the floor level, it is indicated that a BC002 that is BASE_CELL is arranged at coordinates (1000, 0) with respect to an origin (white dot) 365 at the floor level.

An arrangement layout 362 at the cell level indicates that CONV002 is disposed at coordinates (0, 0), the RO100 is disposed at coordinates (0, 500), and TS001 is disposed at coordinates (0, 1500) respectively with respect to an origin (black dot) 366 at the cell level.

### <Processing Unit>

Returning to FIG. 1, the processing unit 120 includes an arrangement possible area extracting unit 121, an arrangement pattern calculating unit 122, and a facility configuration optimizing unit 123.

The arrangement possible area extracting unit 121 extracts a region where a facility can be arranged at respective layers of the arrangement level 231 based on the arrangement restriction. The arrangement possible area can be obtained based on a profile of the arrangement level and a restriction level that corresponds to (is equal to) the arrangement level. For example, the profile of the floor is included in administration information not illustrated in the drawing, and a profile of the cell can be determined based on a size of BASE_CELL.

In such processing, with respect to the arrangement restriction at the floor level, processing is necessary for each item whose arrangement is restricted. On the other hand, in the arrangement restriction at the cell level, with respect to the restriction information that is standardized at every cell, reprocessing may not be performed by additionally recording a result that is processed once. That is, in a case where the cell type and the facility to be arranged of the new cell are equal to the cell type and the facility of the past cell, the arrangement layout of the past cell can be used. In this manner, by making use of the past processing result as the standard information, it is possible to acquire an advantageous effect of reducing a load of the processing.

The arrangement pattern calculating unit 122 calculates the combination patterns of arrangeable facility groups based on information on arrangement possible areas extracted by processing in the arrangement possible area extracting unit 121 and information of the facility candidate groups arrangeable on the layer.

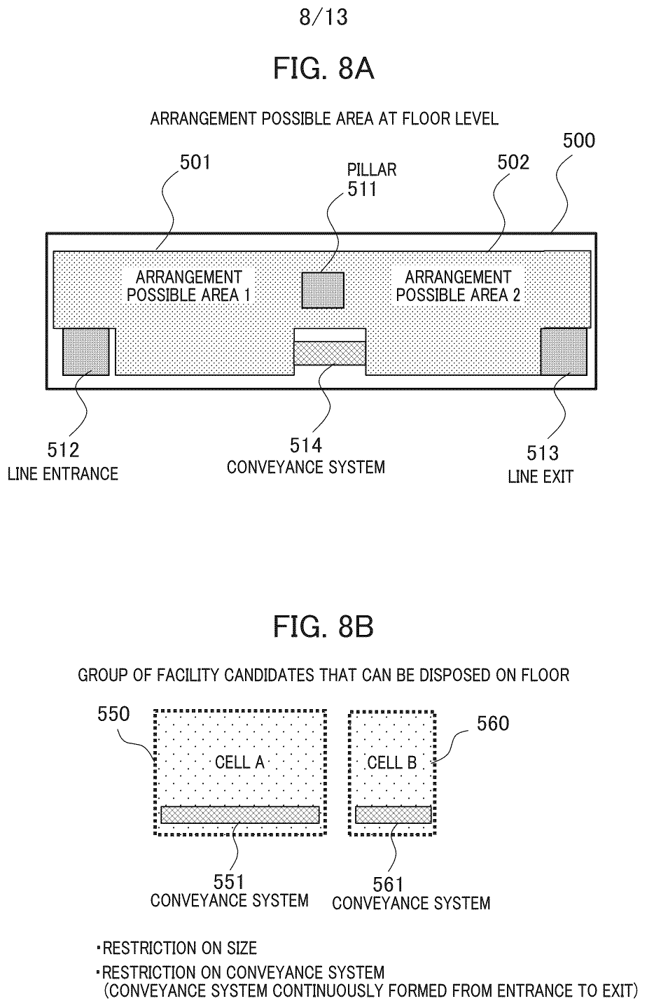

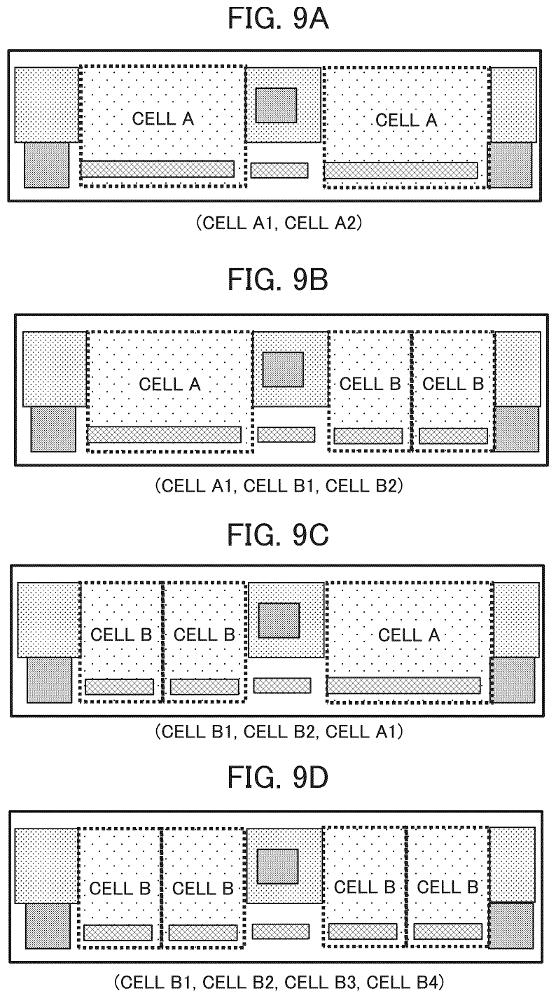

FIG. 8A to FIG. 9D are views illustrating calculation examples of the arrangement pattern at the floor level. FIG. 8A is the example of the arrangement possible area at the floor level. With respect to a floor 500, the arrangement restriction exists at an entrance 512 and at an exit 513 of a line, a pillar 511 and a conveyance system 514, and floor arrangement possible areas 501, 502 are extracted.

FIG. 8B indicates a cell A550 and a cell B560 that differ in size from each other as a facility candidate group that can be arranged on the floor. As the arrangement restriction at the cell level, the restriction on the sizes of the cells and the restriction on the conveyance systems 551, 561 exist.

FIG. 9A to FIG. 9D indicate different patterns of the cells that can be arranged on the floor 500. The possible cell arrangement patterns are limited to four patterns illustrated in FIG. 9A to FIG. 9D. From these drawings, it is understood that the number of cells that are mounted, that is, the number of steps is four at maximum. With such maximum number of steps, the number of combination candidates at the time of deciding the facility configuration can be reduced by the facility configuration optimizing unit 123 and hence, it is possible to acquire an advantageous effect of reducing a load of the processing.

In the same manner, also at the cell level, an arrangement patten can be extracted with respect to a facility candidate group that can be arranged in the cell and hence, it is possible to acquire an advantageous effect of reducing a load of processing in the facility constitution optimizing unit 123.

The facility constitution optimizing unit 123 generates step design information 115 and arrangement design information 116 that satisfy various conditions relating to the product information 111, the production condition information 112, the facility information 113, the operation time information 117 on part-resource candidates, the arrangement restriction information 114, and the combination pattern information that the arrangement pattern calculating unit 122 calculates.

### <Communication Unit, Input Unit, Output Unit>

The communication unit 130 performs the transmission and the reception of signals with other devices with respect to various kinds of information via a network. The input unit 140, for example, receives input information that is displayed and manipulated on a screen, and is inputted when a user manipulates a keyboard or a mouse.

The output unit 150, for example, prepares screen information that includes information outputted as a result of performing predetermined processing, and outputs the screen information to a display-use calculator or a display device of the production line design device 100 via the communication unit 130.

### <Hardware Configuration>

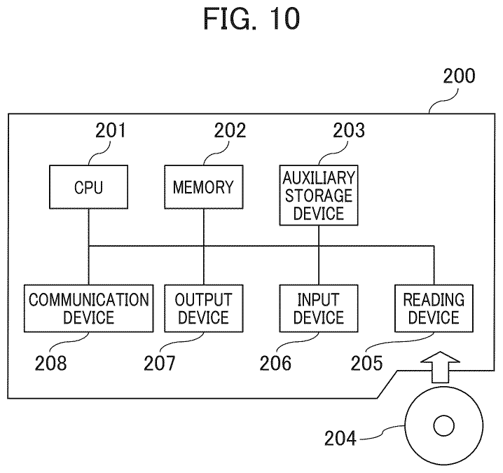

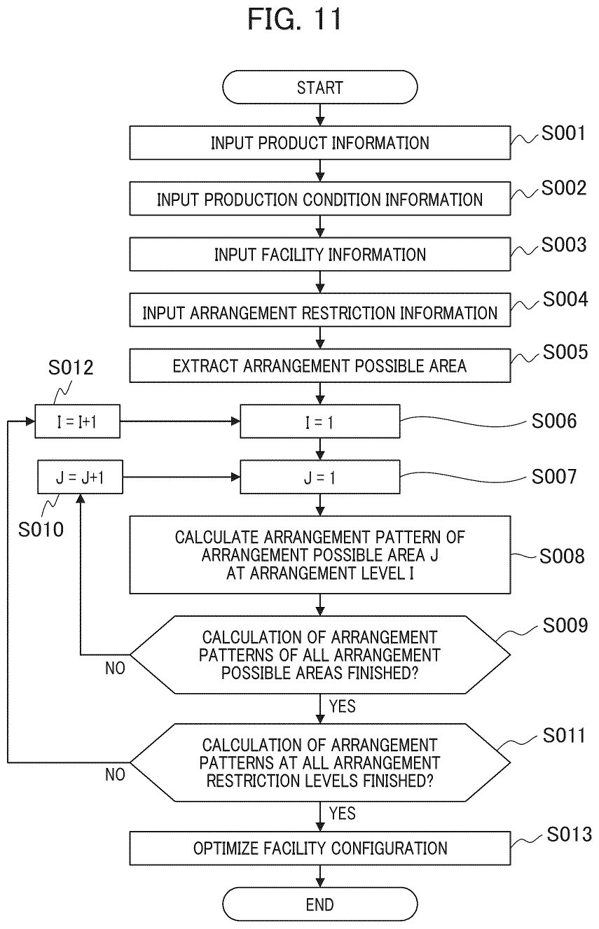

FIG. 10 is a block diagram illustrating a hardware configurational example of the production line design device 100. The production line design device 100 can be realized by a general-use computer 200, for example. The computer 200 includes a processor (for example, a CPU, a GPU or the like) 201, a memory 202 such as a random access memory (RAM), and an auxiliary storage device 203 such as a hard disc drive (HDD) or a solid state drive (SSD).

The computer 200 further includes: a reading device 205 that reads information with respect to a storage medium 204 that has portability such as a CD or DVD; an input device 206 such as a keyboard and a mouse, a barcode reader, or a touch panel; an output device 207 such as a display; and a communication device 208 that communicates with other computers via a communication network such as LAN or Internet.

The production line design device 100 can be realized by a network system that includes a plurality of such computers 200. It is needless to say that the reading device 205 performs not only reading from the storage medium 204 having portability but also writing to the storage medium 204.

For example, the arrangement possible area extracting unit 121, the arrangement pattern calculating unit 122 and the facility configuration optimizing unit 123 included in the processing unit 120 can be realized by loading a predetermined program stored in the auxiliary storage device 203 to the memory 202 and by executing the program by the processor 201.

The input unit 140 can be realized by allowing the processor 201 to utilize the input device 206. The output unit 150 can be realized by allowing the processor 201 to utilize the output device 207 or the communication device 208. The communication unit 130 can be realized by allowing the processor 201 to utilize the communication device 208. The storage unit 110 can be realized by allowing the processor 201 to utilize the memory 202 or the auxiliary storage device 203.

The predetermined program is downloaded to the auxiliary storage device 203 from the storage medium 204 having portability via the reading device 205 or from a network via the communication device 208 and, then, may be loaded up to the memory 202 and may be executed by the processor 201. Alternatively, the predetermined program may be directly loaded up to the memory 202 from the storage medium 204 having portability via the reading device 205 or from the network via the communication device 208, and may be executed by the processor 201.

### <Production Line Design Processing>

11 is a flowchart illustrating an example of the flow of production line design processing. The production line design processing is started when the computer 200 receives a start instruction from a user via the interface device.

First, the input unit 140 receives inputting of product information that is an object of a production line to be designed (step S001). The received product information is stored in the product information 111. The product information 111 is defined and stored for every product that is an object of designing.

The input unit 140 receives inputting of production condition information (step S002). The received production condition information is stored in the production condition information 112. All processing that succeed such processing are performed so as to satisfy a target tact time set here. In a case where the production line is constituted of a plurality of steps, among the tact times of the respective steps, a maximum value becomes the tact time of the entirety of the assembling line. That is, the tact time of the production line agrees with the tact time of the step which becomes a bottle neck. Further, all processing that succeed such processing are performed so as to optimize the target function set here.

The input unit 140 receives inputting of facility information (step S003). The received facility information is stored in the facility information 113. The facility information 113 is defined and stored for every product that becomes an object of designing. Further, common information may be stored in advance in the storage unit 110 of the production line design device 100 irrelevant to an object of designing. Further, selected inputting may be received as facility information designated based on information stored in advance.

The input unit 140 further receives operation time information on part-resource candidates as facility information, and stores the operation time information in the operation time information 117 of the part-resource candidates. This information may be stored in the storage unit 110 of the production line design device 100 in advance. Further, selected inputting may be received as facility information designated based on information stored in advance.

The input unit 140 receives inputting of arrangement restriction information (step S004). The received arrangement restriction information is stored in the arrangement restriction information 114. The arrangement restriction information 114 is defined and stored for every product that become an object of designing. Further, common information may be stored in advance in the storage unit 110 of the production line design device 100 irrelevant to an object of designing. Further, selected inputting may be received as arrangement restriction information that is designated based on information stored in advance.

Then, the arrangement possible area extracting unit 121 extracts arrangement possible areas at respective layers of the arrangement using the respective information that received inputting (step S005). The arrangement possible area extracting unit 121 decides the arrangement possible areas at the respective arrangement levels that the arrangement levels 231 of the facility information 113 indicate based on the restriction levels 241 corresponding to the respective arrangement areas.

The arrangement pattern calculating unit 122 initializes a valuable I (I being an integer) for selecting the layer of the arrangement level that is a processing object, and sets the valuable I to 1 (I=1) (step S006).

Next, in the layer of the selected arrangement level, the arrangement pattern calculating unit 122 initializes a valuable J (J being an integer) for selecting the arrangement possible area as a processing object, and sets the valuable J to 1 (J=1) (step S007).

Next, the arrangement pattern calculating unit 122 generates an arrangement pattern using the respective inputted information and arrangement possible area information that the arrangement possible area extracting unit 121 extracts with respect to the arrangement possible area J at the arrangement restriction level I (step S008). In the generation of facility arrangement patterns in the respective layers, the restriction levels equal to or below the restriction levels corresponding to the respective layers are referenced. In the above-mentioned example, in the generation of the facility arrangement pattern in the cell, the restriction on the cell level and the restriction on the robot level are referenced.

The arrangement pattern calculating unit 122 determines whether or not the arrangement patterns of all arrangement possible areas are calculated (step S009). In a case where unprocessed candidates remain (“NO” in step S009), the arrangement pattern calculating unit 122 adds 1 to the valuable J (step S010), returns the control to the step S007, and selects the next arrangement possible area.

In a case where no unprocessed candidates remain (“YES” in step S009), the arrangement pattern calculating unit 122 determines whether or not the arrangement patterns of all arrangement restriction levels are calculated (step S011). In a case where unprocessed candidates remain (“NO” in step S011), the arrangement pattern calculating unit 122 adds 1 to the valuable I (step S012), returns the control to step S006, and selects the next arrangement restriction level.

In a case where no unprocessed candidates remain (“YES” in step S011), the facility configuration optimizing unit 123 generates step design information and arrangement design information using the respective inputted information, the arrangement possible area information that the arrangement possible area extracting unit 121 extracts, and the arrangement pattern information that the arrangement pattern calculating unit 122 generates (step S013). The generated information are respectively stored in the step design information 115 and the arrangement design information 116.

One example of the flow of the production line design processing has been described heretofore.

### <Output Display Example>

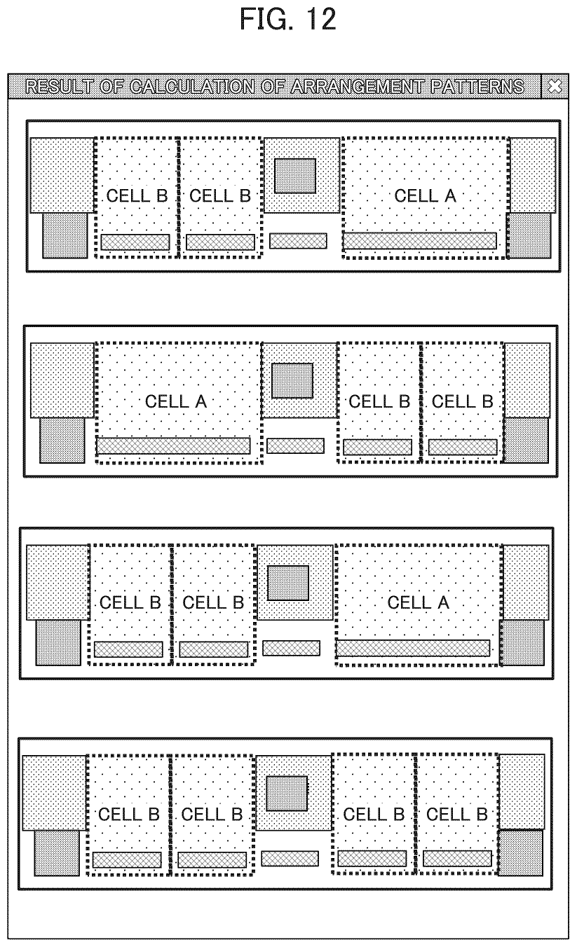

FIG. 12 is a view illustrating examples of a display screen that display results of the arrangement patterns that the arrangement pattern calculating unit 122 calculates. FIG. 12 illustrates four arrangement patterns described with reference to FIG. 9A to FIG. 9D. The arrangement pattern calculating unit 122 may display the arrangement patterns at the respective different arrangement levels. Alternatively, the arrangement pattern calculating unit 122 may display the combination of patterns at the different arrangement levels that are associated with each other.

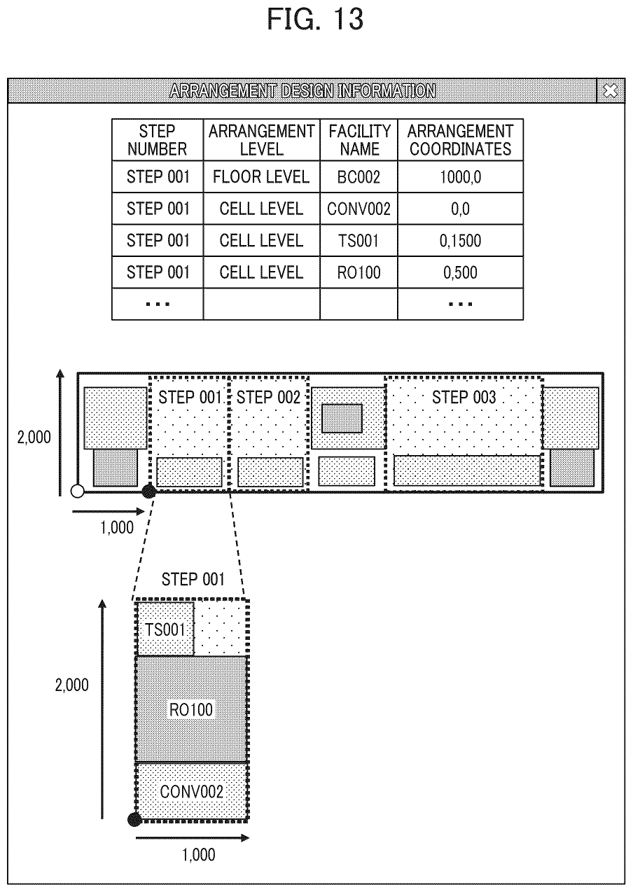

FIG. 13 is a view illustrating an example of a display screen of the arrangement design information that the facility configuration optimizing unit 123 calculates. FIG. 13 illustrates the arrangement design information that is described with reference to FIG. 7A and FIG. 7B. The facility configuration optimizing unit 123 may display the step design information illustrated in FIG. 6 in place of the arrangement design information or in addition to the arrangement design information.

The configurational example of the production line design system according to the present embodiment has been described heretofore. According to the production line design system, it is possible to plan the step design information and the arrangement design information of the production line that satisfy the client specification within a short time and optimizes a target function by eliminating a return work without relying on the knowhows of engineers. That is, it is possible to create a production line design plan that suppresses an investment cost with ease.

The above-mentioned embodiment is described in detail for describing the present invention in an easily understandable manner. Accordingly, it is not always the case that the present invention is limited to the invention that includes all configurations described in the embodiment. Some parts of the configurations of the embodiment may be replaced with other configurations. Further, some parts of the configurations of the embodiment may be deleted.

With respect to the respective units, the respective configurations, functions, processing units and the like described above, some parts or the entirety of these may be realized by a hardware by designing using an integrated circuit, for example. Further, the respective unit, the respective configuration, functions, and the like described above may be realized by software by allowing the processor to interpret programs that realize the respective functions and by allowing the processor to execute the programs. Information on the programs, the tables, the files and the like for realizing the respective functions can be installed in a recording device such as a memory and a hard disc, or, a storage medium such as an IC card, an SD card, a DVD and the like.

Control lines and information lines according to the embodiment described above are indicated so long as they are considered necessary for the explanation of the invention, and it is not always the case that all control lines and information lines used in the product are described. It is considered that, in an actual production line design system, almost all configurations are mutually connected with each other. The present invention has been described heretofore by mainly focusing on the embodiment.

### LIST OF REFERENCE SIGNS

1: production line system
100: production line design device
110: storage unit
111: product information
112: production condition information
113: facility information
114: arrangement restriction information
1141: floor level
1142: cell level
115: step design information
116: arrangement design information
120: processing unit
121: arrangement possible area extracting unit
122: arrangement pattern calculating unit
123: facility configuration optimizing unit
130: communication unit
140: input unit
150: output unit

1. A production line design system comprising:
a processor; and
a storage device, wherein
the storage device is configured to store:
facility information that indicates facilities used in a production line of an object product, and arrangement levels of regions having an inclusion relationship in which the facilities are respectively arranged; and
arrangement restriction information that defines arrangement restriction on the facilities by dividing the arrangement restriction into restriction levels each corresponding to the regions having the inclusion relationship,
the processor is configured to extract a facility arrangement possible area at the respective arrangement levels based on the information on the facility and the arrangement restriction information, and
the processor is configured to decide an arrangement pattern candidate of the facilities with respect to the extracted respective arrangement possible areas that are extracted based on the facility information and the arrangement restriction information.

2. The production line design system according to claim 1,
the arrangement level and the restriction level respectively include a floor level at which the production line is arranged and a cell level included in the production line.

3. The production line design system according to claim 1, wherein
the storage device stores:
information on an object product of the production line;
production condition information indicating required specification of production of the object product; and
operation time information on the object product by the facility, and
the processor is configured to decide combination of facility configurations of the production line based on the arrangement pattern candidates, the production condition information and the operation time information.

4. The production line design system according to claim 1, wherein
the arrangement restriction information defines an interference object, a method of fixing the facility, and a method of conveying the object product.

5. The production line design system according to claim 2, wherein
the arrangement restriction information defines restriction based on a shape of a line at the floor level.

6. The production line design system according to claim 2, wherein
the arrangement restriction information defines a restriction level of the facility arranged in the cell as a lower-order layer of the cell level.

7. The production line design system according to claim 2, wherein
the arrangement restriction information includes a result of past processing as standard information in restriction information at the cell level.

8. A method of designing a production line performed by a system, wherein
the system is configured to store:
facility information that indicates facilities used in a production line of an object product, and arrangement levels of regions having an inclusion relationship in which the facilities are respectively arranged; and
arrangement restriction information that defines the arrangement restriction on the facilities by dividing the arrangement restriction into restriction levels each corresponding to the regions having the inclusion relationship,
the method of designing a production line includes a step where the system:
extracts a facility arrangement possible area in the respective arrangement levels based on the facility information and the arrangement restriction information; and
decides an arrangement pattern candidate of the facilities with respect to the respective extracted arrangement possible areas based on the facility information and arrangement restriction information.
